(19) United States
(12) Patent Application Publication
(10) Pub. No.: US 2025/0351491 A1
(43) Pub. Date: Nov. 13, 2025

(54) SEMICONDUCTOR DEVICE AND METHOD FOR MANUFACTURING THE SAME

(71) Applicant: Murata Manufacturing Co., Ltd., Kyoto-fu (JP)

(72) Inventors: Mitsuhiro NAKAMURA, Nagaokakyo-shi (JP); Kenji SASAKI, Nagaokakyo-shi (JP)

(73) Assignee: Murata Manufacturing Co., Ltd., Kyoto-fu (JP)

(21) Appl. No.: 19/191,628

(22) Filed: Apr. 28, 2025

(30) Foreign Application Priority Data
May 9, 2024 (JP) 2024-076561

(51) Int. Cl. H10D 62/13; H10D 10/01; H10D 10/80; H10D 64/01; H10D 64/27

(52) U.S. Cl. CPC H10D 62/133; H10D 10/021; H10D 10/821; H10D 62/137; H10D 64/01; H10D 64/281

(57) ABSTRACT

In a semiconductor device, on a surface of a collector layer including a compound semiconductor of a first conductor type, facing in a first direction, a base layer including a compound semiconductor of a second conductor type opposite from the first conductor type is disposed. On a partial region of a surface of the base layer facing in the first direction, at least one emitter mesa including a compound semiconductor of the first conductor type and forming a heterojunction with the base layer is disposed. A collector electrode is on a surface of the collector layer facing in a second direction opposite to the first direction. An emitter electrode is on a surface of the emitter mesa facing in the first direction. A base electrode is on a region, in the surface of the base layer facing in the first direction, on which the emitter mesa is not disposed.

### CROSS-REFERENCE TO RELATED APPLICATION

This application claims benefit of priority to Japanese Patent Application No. 2024-076561, filed May 9, 2024, the entire content of which is incorporated herein by reference.

### BACKGROUND

### Technical Field

The present disclosure relates to a semiconductor device and a method for manufacturing the semiconductor device.

### Background Art

Japanese Unexamined Patent Application Publication (Translation of PCT Application) No. 2021-506114 proposes an improved version relative to an existing heterojunction bipolar transistor (HBT) including an emitter in a stripe. In the improved HBT, a base layer is disposed on a collector layer, and an emitter mesa is disposed on the base layer. The emitter mesa has multiple cavities, and a base electrode is disposed in each of the multiple cavities.

### SUMMARY

In the HBT disclosed in Japanese Unexamined Patent Application Publication (Translation of PCT Application) No. 2021-506114, since the base electrode is disposed in the cavity of the emitter mesa, a wire intersecting the emitter mesa needs to be disposed for connecting the isolated multiple base electrodes to a surrounding circuit. In addition, in an existing structure in which an emitter mesa is formed in a stripe, and striped base electrodes are disposed on both sides of the emitter mesa, two striped base electrodes can be connected to each other in the same metal layer, but the base electrodes are elongated, thereby increasing base resistance.

Accordingly, the present disclosure provides a semiconductor device in which a base electrode can be connected to a surrounding wire without intersecting an emitter mesa while base resistance is suppressed from increasing, and a method for manufacturing the semiconductor device.

According to one aspect of the present disclosure, there is provided a semiconductor device including a collector layer including a compound semiconductor of a first conductor type; a base layer disposed on a surface of the collector layer facing in a first direction and including a compound semiconductor of a second conductor type opposite from the first conductor type; at least one emitter mesa disposed on a partial region of a surface of the base layer facing in the first direction and including a compound semiconductor of the first conductor type, the at least one emitter mesa forming a heterojunction with the base layer; a collector electrode disposed on a surface of the collector layer facing in a second direction opposite to the first direction; an emitter electrode disposed on a surface of the emitter mesa facing in the first direction; and a base electrode disposed on a region, in the surface of the base layer facing in the first direction, on which the emitter mesa is not disposed. The base electrode includes a first layer and a second layer, a portion of the first layer overlaps a portion of the second layer, each of the first layer and the second layer includes no closed pattern in plan view, and the first layer and the second layer as a whole continuously surround the emitter mesa in plan view.

According to another aspect of the present disclosure, there is provided a method for manufacturing a semiconductor device. The method includes forming a release layer on a surface of a temporary substrate facing in a first direction; forming a collector layer including a compound semiconductor of a first conductor type on a surface of the release layer facing in the first direction; forming a base layer including a compound semiconductor of a second conductor type opposite from the first conductor type, on a surface of the collector layer facing in the first direction; forming at least one emitter mesa including a compound semiconductor of the first conductor type on a surface of the base layer facing in the first direction; forming a base electrode continuously surrounding the emitter mesa in plan view, on the surface of the base layer facing in the first direction; forming an emitter electrode on a surface of the emitter mesa facing in the first direction; separating the collector layer from the temporary substrate by etching and removing the release layer; forming a collector electrode on a surface of the collector layer facing in a second direction opposite to the first direction; and joining the collector electrode to a support substrate.

The base electrode continuously surrounds the emitter mesa in plan view, thereby being able to suppress an increase in base resistance. In addition, the base electrode can be connected to a surrounding wire without intersecting the emitter mesa.

### BRIEF DESCRIPTION OF THE DRAWINGS

FIG. 1 is a plan view of a semiconductor device according to a first embodiment;

FIG. 2 is a sectional view taken along dot-and-dash line 2-2 in FIG. 1;

FIGS. 3A, 3B, and 3C are sectional views of the semiconductor device according to the first embodiment in the middle of manufacturing;

FIG. 4A is a plan view of the semiconductor device in the middle of manufacturing, and FIG. 4B is a sectional view taken along dot-and-dash line 4B-4B in FIG. 4A;

FIG. 5A is a plan view of the semiconductor device in the middle of manufacturing, and FIG. 5B is a sectional view taken along dot-and-dash line 5B-5B in FIG. 5A;

FIG. 6 is a plan view of a semiconductor device according to a modification example of the first embodiment;

FIG. 7 is a plan view of a semiconductor device according to another modification example of the first embodiment;

FIG. 8 is a plan view of a semiconductor device according to a second embodiment;

FIGS. 9A and 9B are plan views of a first layer and a second layer of a base electrode 30B, respectively;

FIG. 10 is a sectional view taken along dot-and-dash line 10-10 in FIG. 8;

FIG. 11 is a plan view of a semiconductor device according to a modification example of the second embodiment;

FIGS. 12A and 12B are plan views of a first layer and a second layer of a base electrode of the semiconductor device illustrated in FIG. 11, respectively;

FIG. 13 is a plan view of a semiconductor device according to a third embodiment;

FIG. 14 is a sectional view of a semiconductor device according to a fourth embodiment;

FIG. 15 is a sectional view of a semiconductor device according to a fifth embodiment;

FIGS. 16A and 16B are sectional views of the semiconductor device according to the fifth embodiment in the middle of manufacturing; and

FIG. 17 is a sectional view of a semiconductor device according to a sixth embodiment.

### DETAILED DESCRIPTION

### First Embodiment

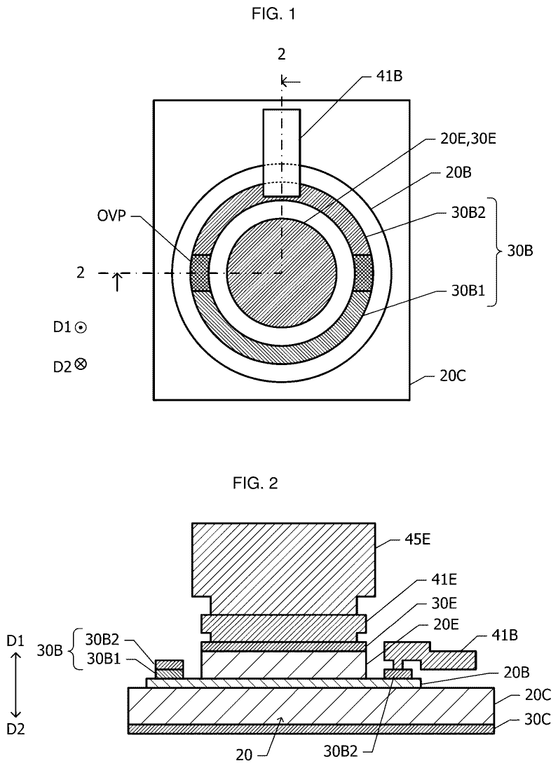

A semiconductor device according to a first embodiment will be described with reference to FIGS. 1 to 5B.

FIG. 1 is a plan view of the semiconductor device according to the first embodiment, and FIG. 2 is a sectional view taken along dot-and-dash line 2-2 in FIG. 1. Note that illustration of an interlayer insulating film is omitted in FIG. 2.

A base layer 20B is disposed on a partial region of a surface of a collector layer 20C facing in a first direction D1 (the surface facing frontward in FIG. 1, the surface facing upward in FIG. 2). An emitter mesa 20E is disposed on a surface of the base layer 20B facing in the first direction D1. The shapes of the base layer 20B and the emitter mesa 20E are each circular in plan view. In the present specification, surfaces of parts facing in the first direction DI are each sometimes referred to as an upper surface.

The collector layer 20C includes a compound semiconductor of a first conductor type, and the base layer 20B includes a compound semiconductor of a second conductor type opposite from the first conductor type. Here, in the “first conductor type” and the “second conductor type”, one refers to an n-type conductivity type, and the other refers to a p-type conductivity type. The emitter mesa 20E includes a compound semiconductor of the first conductor type. The base layer 20B and the emitter mesa 20E form a heterojunction. For example, the collector layer 20C is made of n-type GaAs, the base layer 20B is made of p-type GaAs, and the emitter mesa 20E is made of n-type InGaP. The collector layer 20C, the base layer 20B, and the emitter mesa 20E constitute a heterojunction bipolar transistor (HBT) 20.

Note that there may be adopted a so-called ledge structure in which a compound semiconductor layer of the first conductor type is disposed on the entire upper surface of the base layer 20B, and an emitter cap layer and a contact layer are disposed on a portion of a surface of the compound semiconductor layer. In this structure, a region, in the compound semiconductor layer of the first conductor type covering the upper surface of the base layer 20B, overlapping the emitter cap layer, the emitter cap layer, and the contact layer correspond to the emitter mesa 20E. In the compound semiconductor layer of the first conductor type covering the entire upper surface of the base layer 20B, a region not covered with the emitter cap layer acts as a protective film of the base layer 20B.

An emitter electrode 30E is disposed on the entire upper surface of the emitter mesa 20E. In FIG. 1, the emitter electrode 30E is hatched with oblique lines rising to the right. The emitter electrode 30E is in ohmic contact with the emitter mesa 20E. The emitter electrode 30E and the emitter mesa 20E are patterned by using, for example, a self-alignment process.

A base electrode 30B is disposed on a region, in the surface of the base layer 20B facing in the first direction D1, on which the emitter mesa 20E is not disposed. The base electrode 30B is in ohmic contact with the base layer 20B. The base electrode 30B continuously surrounds the emitter mesa 20E in plan view. That is, the emitter mesa 20E is disposed inside a closed pattern constituted by the base electrode 30B. Such a “closed pattern” here refers to a pattern in which, when moving in one direction along the pattern, a point returns to the original position. The interval between the outer peripheral line of the emitter mesa 20E and the inner peripheral line of the base electrode 30B is substantially constant in a peripheral direction. The emitter mesa 20E is processed by using, for example, dry etching. Note that the thickness of the emitter mesa 20E is, for example, 200 nm or less.

The base electrode 30B includes a first layer 30B1 and a second layer 30B2. In FIG. 1, the first layer 30B1 is hatched with oblique lines going down to the right, and the second layer 30B2 is hatched with oblique lines rising to the right. A portion of the first layer 30B1 overlaps a portion of the second layer 30B2, and each of the first layer 30B1 and the second layer 30B2 includes no closed pattern in plan view. The first layer 30B1 and the second layer 30B2 as a whole continuously surround the emitter mesa 20E in plan view.

For example, each of the first layer 30B1 and the second layer 30B2 has a circular arc shape along the common circumference in plan view, and end portions of both overlap each other. That is, the sum of the central angle of the circular arc along which the first layer 30B1 extends and the central angle of the circular arc along which the second layer 30B2 extends is larger than 360 degrees. In an overlap region OVP, the first layer 30B1 is disposed closer to the base layer 20B than the second layer 30B2.

An extreme end of a first-layer base wire 41B overlaps a portion of the upper surface of the base electrode 30B, and the base wire 41B extends outside the base layer 20B in plan view. A first-layer emitter wire 41E is disposed on the upper surface of the emitter electrode 30E. An emitter bump 45E for external circuit connection is disposed on the upper surface of the emitter wire 41E. In FIG. 1, illustration of the emitter wire 41E and the emitter bump 45E is omitted.

A collector electrode 30C is disposed on a surface of the collector layer 20C facing in a second direction D2 opposite to the first direction D1. The collector electrode 30C is in ohmic contact with the collector layer 20C. In the present specification, surfaces of parts facing in the second direction D2 are each sometimes referred to as a “lower surface”.

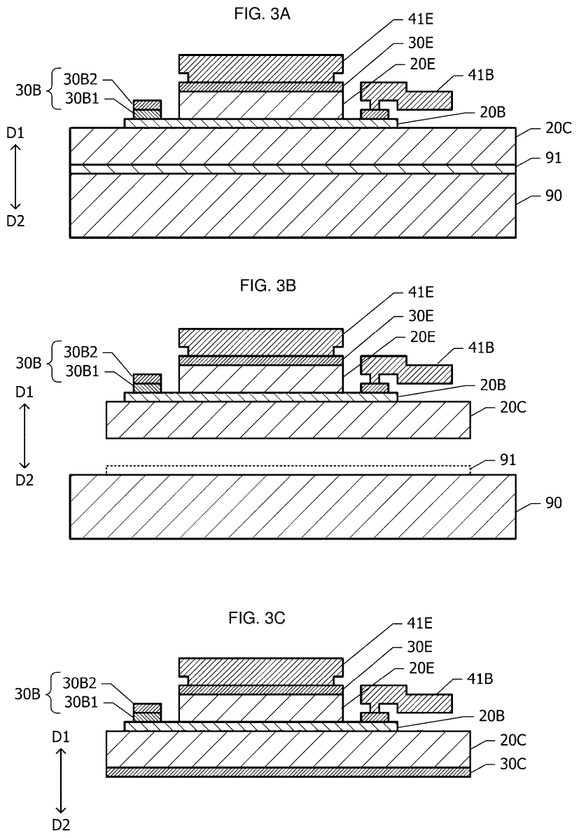

Next, a method for manufacturing the semiconductor device according to the first embodiment will be described with reference to FIGS. 3A, 3B, and 3C. FIGS. 3A, 3B, and 3C are sectional views of the semiconductor device according to the first embodiment in the middle of manufacturing.

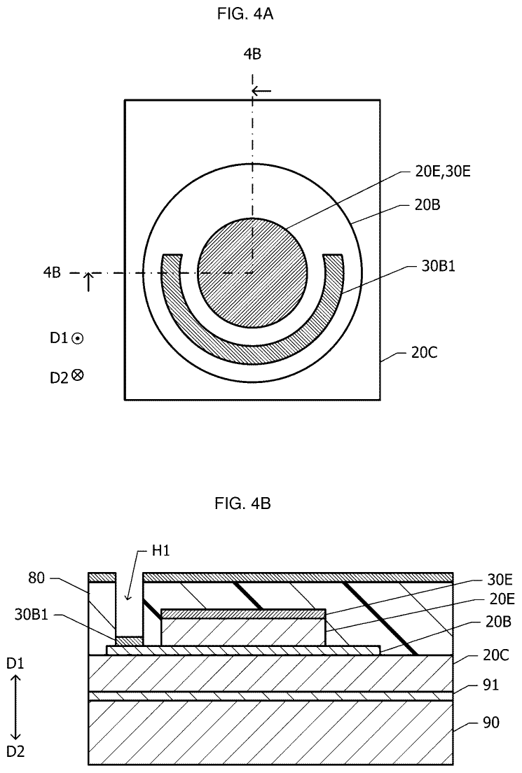

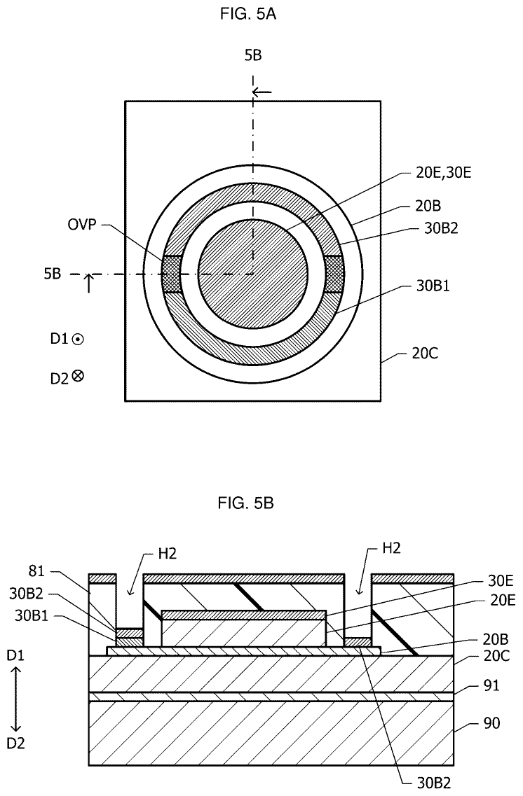

As FIG. 3A illustrates, a release layer 91 is epitaxially grown on a temporary substrate 90 made of a compound semiconductor. Further, the collector layer 20C is epitaxially grown on the release layer 91. An element structure including the base layer 20B, the emitter mesa 20E, the base electrode 30B, the emitter electrode 30E, the first-layer base wire 41B, and the first-layer emitter wire 41E is formed on the upper surface of the collector layer 20C. The above constituents can be formed by typical semiconductor processes. The procedure for forming the base electrode 30B will be described in detail later with reference to FIGS. 4A to 5B.

In this stage, the collector layer 20C is disposed on the entire upper surface of the temporary substrate 90, and element structures (chips) of multiple semiconductor devices are disposed on the upper surface of the collector layer 20C. FIG. 3A illustrates only one chip part. Note that one chip also includes, for example, multiple heterojunction bipolar transistors 20 and other passive elements (not illustrated).

As FIG. 3B illustrates, the collector layer 20C and the release layer 91 are patterned to be divided on a chip basis. In this stage, multiple chips are supported by the temporary substrate 90 that is common thereto. A protective tape (not illustrated) is stuck on the upper surfaces of the multiple chips. The multiple chips are coupled to one another by the protective tape.

The release layer 91 is selectively etched and removed, and the chips each including the collector layer 20C and the like are thus released from the temporary substrate 90. The multiple chips are in a state of being coupled to one another by the protective tape.

As FIG. 3C illustrates, the collector electrode 30C is formed on the lower surface of the collector layer 20C. In one example, after the collector electrode 30C is formed, each of the chips is released from the protective tape, and the collector electrode 30C is joined to, for example, a support substrate. After the chip is joined to the support substrate, the emitter bump 45E (FIG. 2) and the like are formed.

Next, the procedure for forming the base electrode 30B will be described with reference to FIGS. 4A to 5B. FIGS. 4A and 5A are plan views of the semiconductor device in the middle of manufacturing, and FIGS. 4B and 5B are a sectional view taken along dot-and-dash line 4B-4B in FIG. 4A and a sectional view taken along dot-and-dash line 5B-5B in FIG. 5A, respectively. The base electrode 30B is formed by using a lift-off process.

As FIG. 4B illustrates, after the emitter electrode 30E and the emitter mesa 20E are formed, a resist film 80 for covering the collector layer 20C, the base layer 20B, the emitter mesa 20E, and the emitter electrode 30E is formed. Subsequently, a cavity H1 matching a planar pattern of the first layer 30B1 of the base electrode 30B is formed in the resist film 80. A conductor film is formed on the upper surface of the base layer 20B exposed at a bottom plane of the cavity H1 and on the upper surface of the resist film 80. The resist film 80, with the conductor film covering the upper surface of the resist film 80, is removed. As a result of this, the first layer 30B1 of the base electrode 30B remains on the upper surface of the base layer 20B. As FIG. 4A illustrates, the first layer 30B1 includes no closed pattern in plan view.

As FIG. 5B illustrates, after the first layer 30B1 of the base electrode 30B is formed, a resist film 81 for covering the collector layer 20C, the base layer 20B, the emitter mesa 20E, the emitter electrode 30E, and the first layer 30B1 is formed. Subsequently, a cavity H2 matching a planar pattern of the second layer 30B2 of the base electrode 30B is formed in the resist film 81. Inside the cavity H2, in the overlap regions OVP (FIG. 5A), the first layer 30B1 is exposed, and, in the other region, the base layer 20B is exposed.

A conductor film is formed on the upper surfaces of the base layer 20B and the first layer 30B1 exposed at a bottom plane of the cavity H2 and on the upper surface of the resist film 81. The resist film 81, with the conductor film covering the upper surface of the resist film 81, is removed. As a result of this, the second layer 30B2 of the base electrode 30B remains on the upper surface of the base layer 20B and in the overlap regions OVP. As FIG. 5A illustrates, the second layer 30B2 includes no closed pattern in plan view. Note that the first layer 30B1 and the second layer 30B2 as a whole constitute a closed pattern.

Next, advantageous effects of the first embodiment will be described.

In the semiconductor device according to the first embodiment, since the emitter mesa 20E has a circular shape in plan view, and the base electrode 30B (FIG. 1) continuously surrounds the emitter mesa 20E, the base electrode 30B is disposed so as to face the entire outer peripheral line of the emitter mesa 20E. In contrast, in a configuration in which an emitter mesa 20E and a base electrode 30B are formed in strips, there is a portion of the outer periphery of the emitter mesa that no base electrode faces. Thus, in the semiconductor device according to the first embodiment, base resistance can be reduced compared with the configuration in which the emitter mesa 20E and the base electrode 30B are formed in stripes. In addition, the base wire 41B for connecting the base electrode 30B to a surrounding wire does not need to intersect the emitter mesa 20E in plan view.

In addition, since the collector electrode 30C made of a metal material is disposed on the entire lower surface of the collector layer 20C, the resistance of a current path from an external circuit to the collector layer 20C is suppressed from increasing.

Moreover, in the first embodiment, the first layer 30B1 and the second layer 30B2 of the base electrode 30B are formed by different lift-off steps, and the conductor pattern to be formed in the first lift-off process includes no closed pattern. Usually, when a conductor pattern formed by using a lift-off process includes a closed pattern, yield tends to be reduced. In the first embodiment, the base electrode 30B including a closed pattern is formed by the second lift-off process, thereby suppressing reduction in yield.

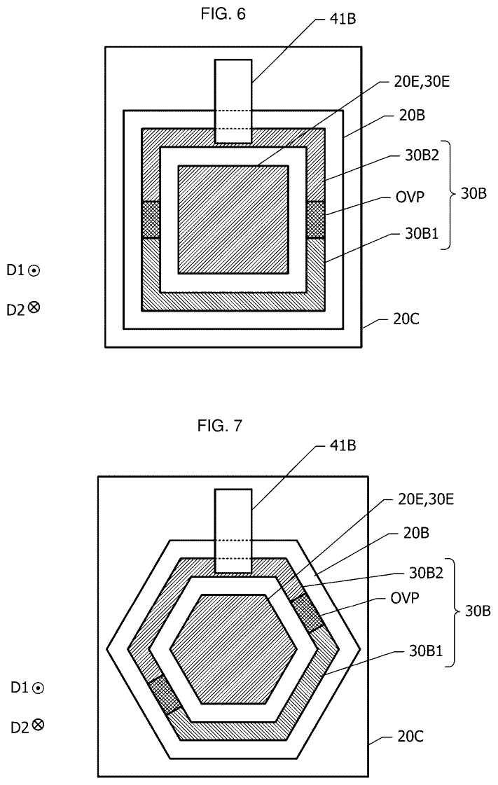

Next, semiconductor devices according to modification examples of the first embodiment will be described with reference to FIGS. 6 and 7. FIGS. 6 and 7 are plan views of the semiconductor devices according to the modification examples of the first embodiment. In the first embodiment (FIG. 1), the pattern of the base electrode 30B is a closed pattern along the circumference in plan view, but other closed patterns may be possible.

In the modification example illustrated in FIG. 6, the pattern of a base electrode 30B is a closed pattern along the outer periphery of a square in plan view. In the example illustrated in FIG. 6, overlap regions OVP are disposed substantially at midpoints of a pair of sides of the square facing each other but may be disposed at other spots. Note that the pattern of the base electrode 30B may be a closed pattern along the outer periphery of a rectangle instead of the square. In the modification example illustrated in FIG. 7, the pattern of a base electrode 30B is a closed pattern along the outer periphery of a regular hexagon in plan view. In the example illustrated in FIG. 7, overlap regions OVP are disposed substantially at midpoints of a pair of sides of the regular hexagon facing each other but may be disposed at other spots. The shape of an emitter mesa 20E in plan view is reflective of the pattern of the base electrode 30B. For example, the shape of the emitter mesa 20E is a square or a rectangle in the modification example illustrated in FIG. 6, and the shape of the emitter mesa 20E is a regular hexagon in the modification example illustrated in FIG. 7.

Next, advantageous effects of the first embodiment and the modification examples thereof will be described.

When the emitter mesa 20E is shaped in a circle as in the first embodiment (FIG. 1), the length of a current path from the outer periphery of the emitter mesa 20E to the base electrode 30B is substantially constant over the entire outer periphery of the emitter mesa 20E. Thus, each base current flows substantially uniformly over almost the entire outer periphery of the emitter mesa 20E. In other words, an advantageous effect of preventing generation of a region of relatively small base current or a region in which little or no base current flows can be obtained.

On the other hand, in the modification examples illustrated in FIGS. 6 and 7, as described in a second embodiment later, structures each constituted by the base electrode 30B and the emitter mesa 20E can be laid all over a two-dimensional plane. Thus, in a configuration in which multiple emitter mesas 20E are disposed, the modification examples illustrated in FIGS. 6 and 7 are better in space usage efficiency.

FIG. 7 illustrates the example in which the base electrode 30B extends along the outer periphery of the regular hexagon, but the base electrode 30B may extend along a hexagon other than the regular hexagon. Note that, when at least one interior angle of a hexagon is an acute angle, little or no base current flows from a spot corresponding to the vertex of the acute angle in the base electrode 30B. To reduce a region in which little or no base current flows, each of the six interior angles of the hexagon is preferably an obtuse angle. In this case, structures each constituted by the base electrode 30B and the emitter mesa 20E are also preferably shaped so that the structures can be laid all over a two-dimensional plane.

Multiple heterojunction bipolar transistors 20 illustrated in each of FIGS. 1, 6, and 7 may be connected in parallel to increase output. In this case, to suppress thermal runaway, a base ballast resistor is preferably connected to each of the heterojunction bipolar transistors 20.

### Second Embodiment

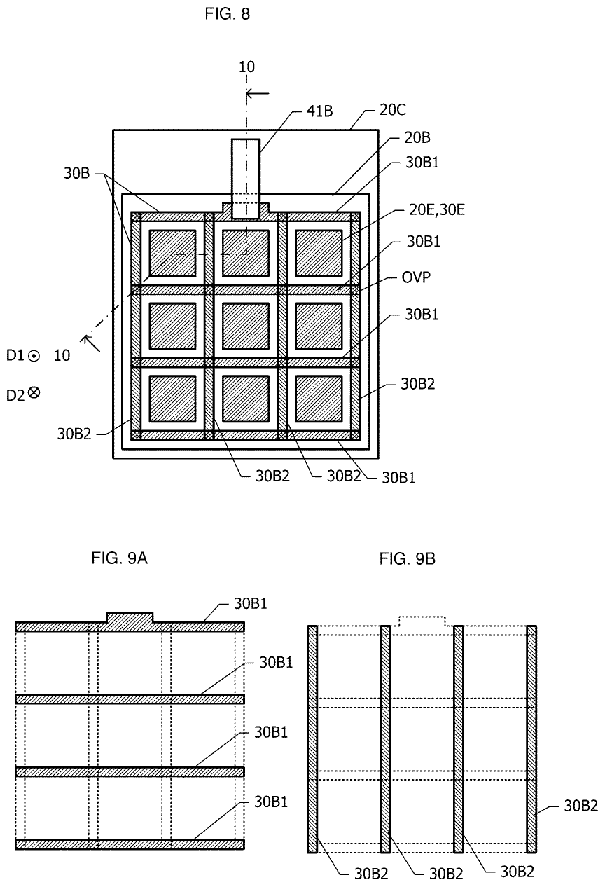

Next, a semiconductor device according to the second embodiment will be described with reference to FIGS. 8 to 10. Hereinafter, the description of a configuration common to the semiconductor devices according to the first embodiment and the modification examples thereof described with reference to FIGS. 1 to 7 is omitted.

FIG. 8 is a plan view of the semiconductor device according to the second embodiment. There is only one emitter mesa 20E in the first embodiment (FIG. 1), but multiple emitter mesas 20E are disposed discretely in the second embodiment. A base electrode 30B continuously surrounds each of the multiple emitter mesas 20E. In the base electrode 30B, a portion disposed between two adjacent emitter mesas 20E is shared as a portion surrounding the emitter mesas 20E on both sides.

More specifically, the base electrode 30B has a lattice shape in which vertical and horizontal lines are orthogonal to each other. The emitter mesas 20E are disposed in respective multiple divisions divided by the vertical lines and the horizontal lines of the lattice shape. In plan view, the outer peripheral line of each of the multiple emitter mesas 20E faces an edge of the base electrode 30B with a gap therebetween and has a shape along the edge of the base electrode 30B. Each of the multiple divisions divided by the lattice pattern in which the vertical lines and the horizontal lines are orthogonal to one another has a square shape or a rectangular shape, and the emitter mesa 20E thus also has a square shape or a rectangular shape in plan view.

The base electrode 30B includes a first layer 30B1 and a second layer 30B2 as with the case of the first embodiment. In FIG. 8, each first layer 30B1 is hatched with oblique lines rising to the right, and each second layer 30B2 is hatched with oblique lines going down to the right. Further, an emitter electrode 30E is hatched with oblique lines rising to the right.

FIGS. 9A and 9B are plan views of the first layer 30B1 and the second layer 30B2 of the base electrode 30B, respectively. The first layer 30B1 (FIG. 9A) and the second layer 30B2 (FIG. 9B) have patterns corresponding to the horizontal line and the vertical line of the lattice shape, respectively. The first layer 30B1 and the second layer 30B2 overlap each other at a lattice point (an overlap region OVP) at which the horizontal line and the vertical line intersect each other. Neither the first layer 30B1 nor the second layer 30B2 includes a closed pattern.

In plan view, a portion of the outermost periphery of the lattice-shaped base electrode 30B is widened, and a first-layer base wire 41B is connected to the widened spot. In plan view, the base wire 41B extends outside a base layer 20B without intersecting any emitter mesa 20E and any emitter electrode 30E.

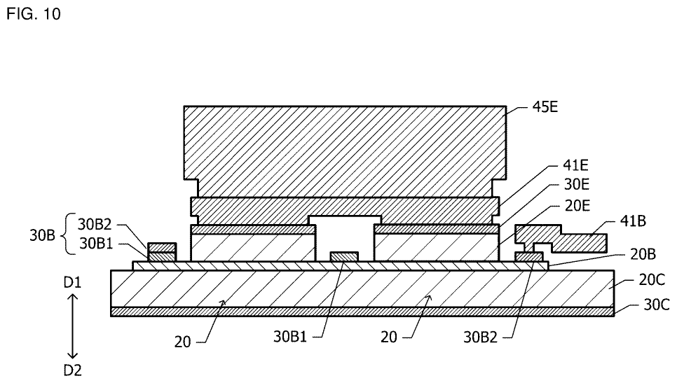

FIG. 10 is a sectional view taken along dot-and-dash line 10-10 in FIG. 8. The multiple emitter mesas 20E are disposed on the upper surface of the base layer 20B. In the section illustrated in FIG. 10, two emitter mesas 20E are appearing. The emitter electrode 30E is disposed on the upper surface of each of the emitter mesas 20E. A first-layer emitter wire 41E electrically connects the multiple emitter electrodes 30E to each other. An emitter bump 45E is disposed on the upper surface of the emitter wire 41E.

The first-layer base wire 41B is electrically connected to the portion of the outermost periphery of the base electrode 30B. The base wire 41B intersects the edge of the base layer 20B and extends outside the base layer 20B in plan view.

Next, advantageous effects of the second embodiment will be described.

In the second embodiment, as with the first embodiment, the base electrode 30B is also disposed so as to face the entire outer peripheral line of the emitter mesa 20E, thereby being able to suppress an increase in base resistance, compared with the configuration in which the emitter mesa 20E and the base electrode 30B are formed in stripes. Moreover, neither the first layer 30B1 nor the second layer 30B2 of the base electrode 30B includes a closed pattern in plan view, thereby suppressing reduction in yield in a forming step of the base electrode 30B.

In addition, the multiple emitter mesas 20E are distributed discretely, thereby being able to make the base electrode 30B electrically continuous in the same layer. In addition, the first-layer base wire 41B does not intersect any of the multiple emitter electrodes 30E in plan view, and the emitter wire 41E disposed in the same conductor layer as the conductor layer including the first-layer base wire 41B can thereby electrically connect all the emitter electrodes 30E to one another. Moreover, the emitter bump 45E disposed on the upper surface of the emitter wire 41E can be electrically connected to the emitter mesa 20E by the shortest path. For example, in plan view, the emitter wire 41E and the emitter bump 45E can be disposed in a region in which the emitter wire 41E and the emitter bump 45E overlap the emitter mesa 20E and the emitter electrode 30E.

In addition, the base electrode 30B (FIG. 8) can be constituted by vertical and horizontal lines. A diagonal line does not fit a grid serving as a guide for pattern arrangement when a pattern is CAD engineered, and a difficulty in laying out thereby arises. In the second embodiment, the pattern of the base electrode 30B can be designed only with vertical and horizontal lines, thereby being able to obtain an advantageous effect of facilitating the laying out of the base electrode 30B.

In the second embodiment, the division divided by the base electrode 30B has a square shape or a rectangular shape but more preferably has a square shape. When the division divided by the base electrode 30B is formed in a square shape, the uniformity of current distribution increases compared with the case of a rectangular shape. Thus, forming the division into a square shape is effective against current collapse.

In addition, although the base electrode 30B has a lattice shape in which the vertical lines and the horizontal lines are orthogonal to one another in the second embodiment, the vertical lines and the horizontal lines are not necessarily strictly orthogonal to one another geometrically and may be slightly deviate from such an orthogonal relationship.

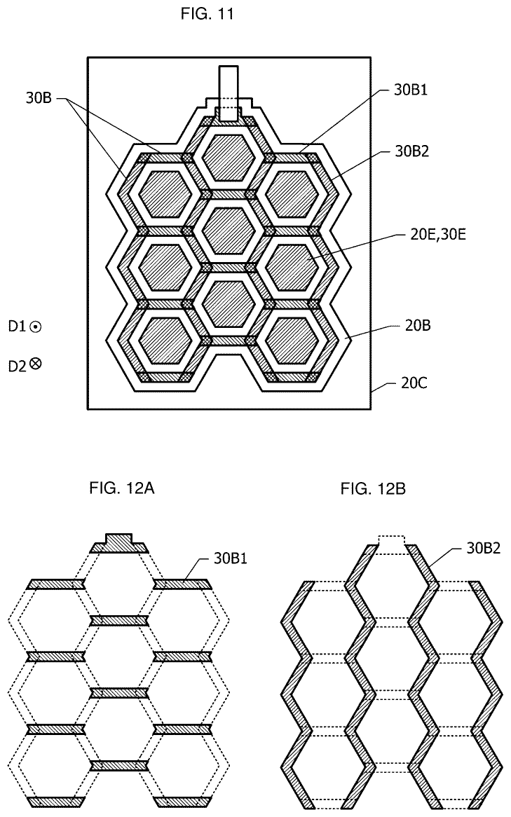

Next, a semiconductor device according to a modification example of the second embodiment will be described with reference to FIGS. 11, 12A, and 12B.

FIG. 11 is a plan view of the semiconductor device according to the modification example of the second embodiment. Although the base electrode 30B has a lattice shape in which the vertical lines and the horizontal lines are orthogonal to one another in the second embodiment (FIG. 8), a base electrode 30B has a honeycomb shape in the present modification example. Multiple regular hexagonal divisions divided by the base electrode 30B are formed. An emitter mesa 20E and an emitter electrode 30E are disposed in each of the multiple divisions. In plan view, the shapes of the emitter mesa 20E and the emitter electrode 30E are reflective of the shape of the division and are thus each a regular hexagon. The base electrode 30B includes a first layer 30B1 and a second layer 30B2 as with the second embodiment.

FIGS. 12A and 12B are plan views of the first layer 30B1 and the second layer 30B2, respectively. As FIG. 12A illustrates, the first layers 30B1 are constituted by multiple portions of the base electrode 30B extending along sides of the regular hexagon that are parallel to one direction (a lateral direction in FIGS. 11 and 12A). As FIG. 12B illustrates, the second layers 30B2 are constituted by multiple portions extending along, in the six sides of the regular hexagon, sides other than the sides along which the first layers 30B1 extend. That is, the second layers 30B2 extend in a zigzag manner in a direction orthogonal to a longitudinal direction of each of the first layers 30B1. End portions of each of the first layers 30B1 overlap corner portions of the corresponding zigzag second layers 30B2.

As in the present modification example, the base electrode 30B may have a honeycomb shape. In the present modification example, each of the first layer 30B1 and the second layer 30B2 includes no closed pattern in plan view.

Note that each of the multiple divisions divided by the base electrode 30B does not necessarily have a regular hexagonal shape and may have a convex hexagonal shape into which a regular hexagon is deformed. Note that, when a vertex of a hexagon is an acute angle, a wasted region, between the emitter mesa 20E and the base electrode 30B, in which practically no base current flows is increased. To reduce this wasted region and to increase area efficiency, the six vertices of a convex hexagon are preferably obtuse angles.

### Third Embodiment

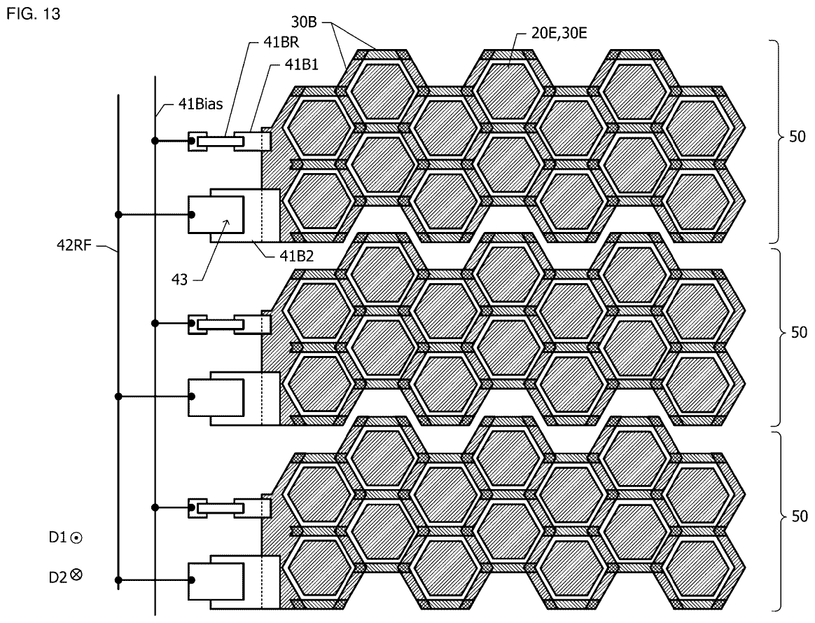

Next, a semiconductor device according to a third embodiment will be described with reference to FIG. 13. Hereinafter, the description of a configuration common to the semiconductor device according to the modification example of the second embodiment described with reference to FIGS. 11, 12A, and 12B is omitted.

FIG. 13 is a plan view of the semiconductor device according to the third embodiment. The semiconductor device according to the third embodiment includes multiple units 50. Each of the multiple units 50 has a configuration similar to that of the semiconductor device according to the modification example of the second embodiment (FIG. 11). Note that the arrangement of multiple emitter mesas 20E of each of the units 50 differs from the arrangement of the emitter mesas 20E of the semiconductor device according to the modification example of the second embodiment illustrated in FIG. 11. A base electrode 30B is provided for each of the units 50, and the base electrodes 30B are not directly connected to one another between the units 50.

First-layer base wires 41B1 and 41B2 connected to the base electrode 30B are disposed in each of the units 50. Multiple base wires 41B are each connected to a common bias wire 41Bias with a base ballast resistance element 41BR therebetween. The other base wires 41B2 are each connected to a common signal input wire 42RF with an input capacitor 43 therebetween.

Next, advantageous effects of the third embodiment will be described.

When the temperature of any one of the units 50 rises, a current concentrates in the unit 50 and raises the temperature of the unit 50 more and more, which causes thermal runaway. In the third embodiment, the base ballast resistance element 41BR is disposed for each of the units 50, thereby being able to suppress current concentration in the unit 50 in which a collector current has relatively increased. Thus, an advantageous effect of hardly causing thermal runaway can be obtained.

Next, a semiconductor device according to a modification example of the third embodiment will be described.

The base electrode 30B of each of the units 50 has a honeycomb shape in the third embodiment but may have a lattice shape in which vertical and horizontal lines are orthogonal to each other as with the base electrode 30B of the semiconductor device according to the second embodiment illustrated in FIG. 8.

### Fourth Embodiment

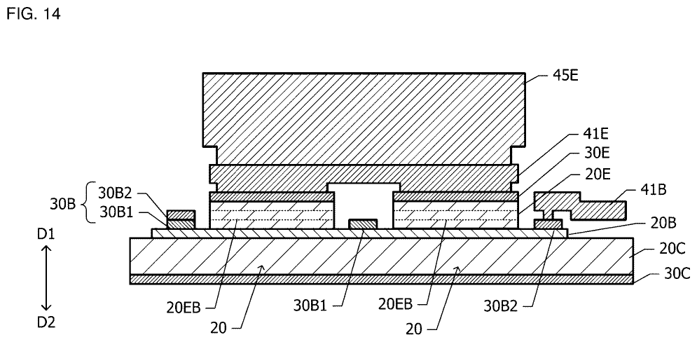

Next, a semiconductor device according to a fourth embodiment will be described with reference to FIG. 14. Hereinafter, the description of a configuration common to the semiconductor device according to the second embodiment described with reference to FIGS. 8 to 10 is omitted.

FIG. 14 is a sectional view of the semiconductor device according to the fourth embodiment. In the fourth embodiment, multiple emitter mesas 20E are also disposed as with the second embodiment (FIGS. 8 and 10). In the first embodiment (FIG. 2), the emitter mesa 20E includes an emitter layer subjected to heterojunction to the base layer 20B, an emitter cap layer, and a contact layer, for example. In contrast, in the third embodiment, each of the emitter mesas 20E further includes a ballast resistor layer 20EB.

The ballast resistor layer 20EB is made of a compound semiconductor in which the resistivity has a positive temperature dependence. For example, the emitter mesa 20E includes an n-type InGaP layer, the ballast resistor layer 20EB made of n-type AlGaAs, an n-type GaAs layer, and an n-type InGaAs layer that are laminated in order from a base layer 20B.

Next, advantageous effects of the fourth embodiment will be described.

When some of the multiple emitter mesas 20E relatively rise in temperature, a current concentrates in the emitter mesa 20E with increased temperature, which causes thermal runaway. In the third embodiment, due to an increase in the resistance of the ballast resistor layer 20EB of the emitter mesa 20E with increased temperature, current concentration in the emitter mesa 20E is suppressed, thereby being able to obtain an advantageous effect of hardly causing thermal runaway.

### Fifth Embodiment

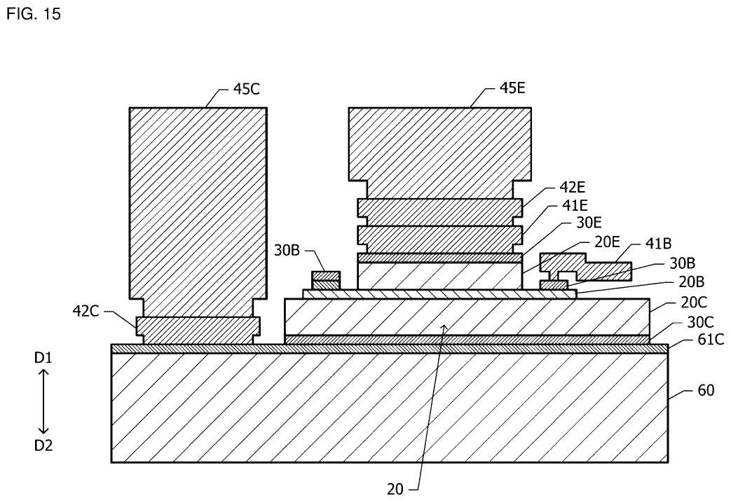

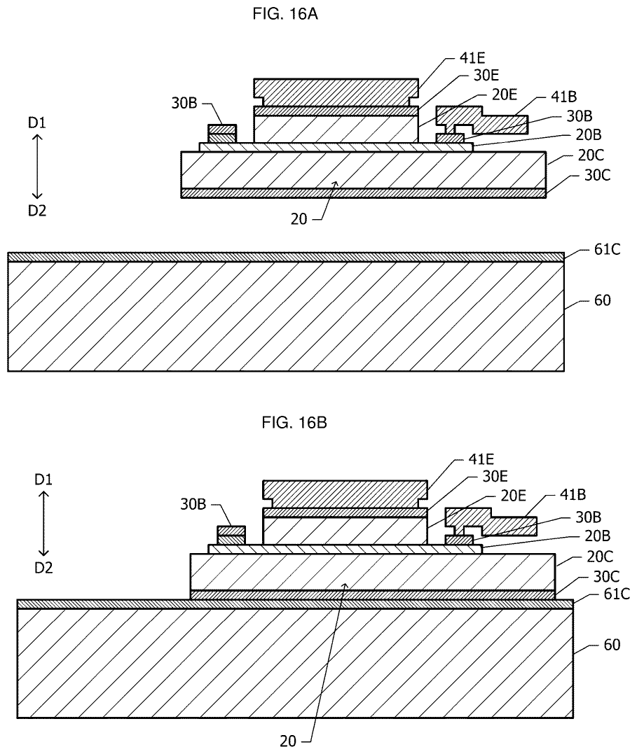

Next, a semiconductor device according to a fifth embodiment will be described with reference to FIGS. 15, 16A, and 16B. Hereinafter, the description of a configuration common to the semiconductor devices according to the first to fourth embodiments described with reference to FIGS. 1 to 14 is omitted.

FIG. 15 is a sectional view of the semiconductor device according to the fifth embodiment. The semiconductor device according to the fifth embodiment includes a support substrate 60 having a mechanically sufficient support force. A substrate having a thermal conductivity higher than the thermal conductivity of a collector layer 20C serves as the support substrate 60. For example, a substrate including silicon (such as a silicon substrate) serves as the support substrate 60.

The semiconductor device according to the fifth embodiment includes an element structure identical to the element structure of the semiconductor device according to the first embodiment (FIG. 2) from the collector electrode 30C to the first-layer emitter wire 41E and the first-layer base wire 41B. Note that the semiconductor device according to the fifth embodiment may include an element structure identical to the element structure of, for example, the semiconductor device according to the second embodiment (FIGS. 8 and 10), the semiconductor device according to the modification example of the second embodiment (FIG. 11), the semiconductor device according to the third embodiment (FIG. 13), or the semiconductor device according to the fourth embodiment (FIG. 14).

A collector wire 61C is disposed on a surface on one side of the support substrate 60. A surface of a collector electrode 30C equivalent to the surface, of the collector electrode 30C of the semiconductor device according to the first embodiment, facing in the second direction D2 is joined to the collector wire 61C, and the collector electrode 30C is electrically connected to the collector wire 61C. In plan view, the support substrate 60 is larger than the collector layer 20C, and the collector wire 61C extends outside the collector electrode 30C.

A collector bump 45C for external circuit connection is disposed on the side ahead in the first direction DI when viewed from the collector wire 61C. In plan view, the collector bump 45C is disposed at a position where the collector bump 45C overlaps the collector wire 61C and does not overlap the collector electrode 30C and the collector layer 20C. A collector wire 42C is disposed between the collector bump 45C and the collector wire 61C, and the collector bump 45C is electrically connected to the collector wire 61C with the collector wire 42C therebetween.

A second-layer emitter wire 42E is disposed on the upper surface of a first-layer emitter wire 41E, and an emitter bump 45E is disposed on the upper surface of the second-layer emitter wire 42E. The emitter bump 45E is electrically connected to an emitter electrode 30E with the emitter wires 42E and 41E therebetween. The emitter wire 42E and the collector wire 42C are disposed in the same wiring layer.

The semiconductor device according to the fifth embodiment is mounted on a module substrate or the like with the emitter bump 45E and the collector bump 45C facing the module substrate or the like.

Next, a method for manufacturing the semiconductor device according to the fifth embodiment will be described with reference to FIGS. 16A and 16B. FIGS. 16A and 16B are sectional views of the semiconductor device according to the fifth embodiment in the middle of manufacturing.

As FIG. 16A illustrates, an element structure from the collector electrode 30C on the lower surface of the collector layer 20C to the first-layer emitter wire 41E and a first-layer base wire 41B is prepared. A method for preparing the element structure is identical to the method for manufacturing the semiconductor device according to the first embodiment described with reference to FIGS. 3A to 5B. The collector wire 61C is formed on a surface on one side of the support substrate 60.

As FIG. 16B illustrates, the collector electrode 30C is caused to face the collector wire 61C, and both are joined. This joining is achieved by, for example, van der Waals bonding or hydrogen bonding. Alternatively, the joining may be achieved by, for example, electrostatic force, covalent bonding, or eutectic alloy bonding.

After the collector electrode 30C is joined to the collector wire 61C, as FIG. 15 illustrates, the second-layer emitter wire 42E and the second-layer collector wire 42C are formed on surfaces, of the element structure and the collector wire 61C, facing in the first direction, and the emitter bump 45E and the collector bump 45C are further formed. The above constituents are formed by using a typical multilayer-wiring-layer forming process.

Next, advantageous effects of the fifth embodiment will be described.

In the fifth embodiment, the support substrate 60 serves as a substrate for mechanically supporting the element structure including an HBT 20 and further functions as a heat-dissipating path from the HBT 20. Usually, the thermal conductivities of the compound semiconductors constituting the collector layer 20C, a base layer 20B, and an emitter mesa 20E of the HBT 20 are lower than the thermal conductivity of the support substrate 60 including silicon. By joining the element structure including the HBT 20 to the support substrate 60 whose thermal conductivity is relatively high, good heat dissipation from the HBT 20 can be ensured.

Moreover, a current path from the collector bump 45C to the collector layer 20C is constituted by the collector wires 42C and 61C and the collector electrode 30C that are each made of a metal material, and the current path includes no semiconductor material. Thus, the resistance from the collector layer 20C to an external circuit to which the collector layer 20C is connected can be suppressed from increasing.

### Sixth Embodiment

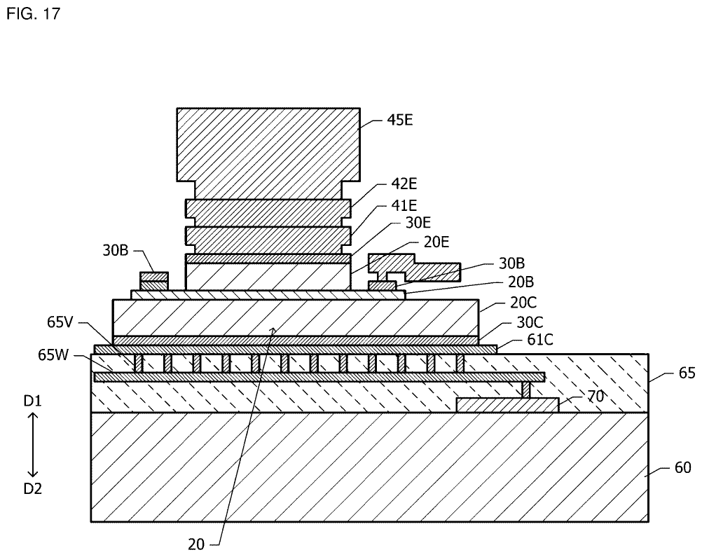

Next, a semiconductor device according to a sixth embodiment will be described with reference to FIG. 17. Hereinafter, the description of a configuration common to the semiconductor device according to the fifth embodiment described with reference to FIGS. 15, 16A, and 16B is omitted.

FIG. 17 is a sectional view of the semiconductor device according to the sixth embodiment. In the semiconductor device according to the fifth embodiment (FIG. 15), the collector bump 45C is disposed on the side ahead in the first direction D1 when viewed from the collector wire 61C. In contrast, in the sixth embodiment, no collector bump is disposed on the side ahead in the first direction DI when viewed from a collector wire 61C.

An electric circuit 70 including a MOSFET and the like is formed on a surface of a support substrate 60 facing in the first direction D1, and a multilayer wiring layer 65 is further formed. The collector wire 61C is disposed on a surface of the multilayer wiring layer 65 facing in the first direction D1. A collector layer 20C of an HBT 20 is electrically connected to the electric circuit 70 with a collector electrode 30C, the collector wire 61C, and a wire 65W and a via 65V in the multilayer wiring layer 65 therebetween. The electric circuit 70 is, for example, a switch element that distributes radio-frequency signals amplified by the HBT 20.

Next, advantageous effects of the sixth embodiment will be described.

In the sixth embodiment, as with the fifth embodiment, the support substrate 60 also functions as a heat-dissipating path from the HBT 20. Moreover, the collector of the HBT 20 can be connected to the electric circuit 70 formed on the support substrate 60, without interposing a bump for external circuit connection therebetween.

The collector electrode 30C made of a metal material is provided on the entire lower surface of the collector layer 20C, and the entire lower surface of the collector electrode 30C is connected to the collector wire 61C. Further, the collector wire 61C is connected to the electric circuit 70 with the wire 65W and the via 65V in the multilayer wiring layer 65 therebetween. A current path from the collector layer 20C to the electric circuit 70 is made of only metal and does not include any portion made of a semiconductor material, thereby suppressing an increase in the resistance of the current path from the electric circuit 70 to the collector layer 20C.

Note that each of the above-described embodiments is an example, and configurations presented in the different embodiments and modification examples may be partially replaced or combined. Similar actions and effects exhibited by similar configurations of the multiple embodiments and modification examples are not referred to, one by one, in each of the embodiments and the modification examples. Moreover, the present disclosure is not limited to the above-described embodiments and modification examples. For example, it will be obvious to those skilled in the art that, for example, various modifications, improvements, and combinations are possible.

The following disclosure is disclosed based on the above embodiments described in the present specification.

<1> A semiconductor device including a collector layer including a compound semiconductor of a first conductor type; a base layer disposed on a surface of the collector layer facing in a first direction and including a compound semiconductor of a second conductor type opposite from the first conductor type; at least one emitter mesa disposed on a partial region of a surface of the base layer facing in the first direction and including a compound semiconductor of the first conductor type, the at least one emitter mesa forming a heterojunction with the base layer; a collector electrode disposed on a surface of the collector layer facing in a second direction opposite to the first direction; an emitter electrode disposed on a surface of the emitter mesa facing in the first direction; and a base electrode disposed on a region, in the surface of the base layer facing in the first direction, on which the emitter mesa is not disposed. The base electrode includes a first layer and a second layer, a portion of the first layer overlaps a portion of the second layer, each of the first layer and the second layer includes no closed pattern in plan view, and the first layer and the second layer as a whole continuously surround the emitter mesa in plan view.

<2> The semiconductor device according to the item <1>, in which the emitter mesa has a circular shape, a square shape, a rectangular shape, or a regular hexagonal shape in plan view.

<3> The semiconductor device according to the item <1>, in which the at least one emitter mesa comprises multiple emitter mesas, the multiple emitter mesas are disposed discretely, the base electrode continuously surrounds each of the emitter mesas, and a portion of the base electrode disposed between two adjacent emitter mesas of the multiple emitter mesas is shared as a portion surrounding the emitter mesas on both sides.

<4> The semiconductor device according to the item <3>, in which at least a portion of the base electrode has, in plan view, a lattice shape in which vertical and horizontal lines are orthogonal to each other, and the multiple emitter mesas are disposed in respective multiple divisions surrounded by the vertical and horizontal lines of the lattice shape.

<5> The semiconductor device according to the item <3>, in which at least a portion of the base electrode has a honeycomb shape in plan view, and the multiple emitter mesas are disposed in respective multiple divisions of the honeycomb shape.

<6> The semiconductor device according to the item <4> or <5>, in which, in plan view, an outer peripheral line of each of the multiple emitter mesas faces an edge of the base electrode with a gap therebetween and has a shape along the edge of the base electrode.

<7> The semiconductor device according to any one of the items <3> to <6>, in which the emitter mesa includes a ballast resistor layer.

<8> The semiconductor device according to any one of the items <1> to <7>, further including an emitter bump for external circuit connection, in which the emitter bump is disposed on a side ahead in the first direction when viewed from the emitter electrode and disposed at a position where the emitter bump partially overlaps the emitter electrode in plan view.

<9> The semiconductor device according to any one of the items <1> to <8>, further including a support substrate including silicon and disposed on a surface of the collector electrode facing in the second direction, in which a thermal conductivity of the support substrate is higher than a thermal conductivity of the collector layer.

<10> The semiconductor device according to the item <9>, further including a collector wire disposed on a surface of the support substrate facing in the first direction, the collector wire being electrically connected to the collector electrode and extending outside the collector electrode in plan view; and a collector bump, for external circuit connection, disposed on a side ahead in the first direction when viewed from the collector wire, the collector bump being disposed at a position, in the collector wire, at which the collector bump does not overlap the collector electrode in plan view, the collector bump being electrically connected to the collector wire.

<11> The semiconductor device according to the item <9>, further including a multilayer wiring layer disposed on a surface of the support substrate facing in the first direction; a collector wire disposed on a surface of the multilayer wiring layer facing in the first direction and electrically connected to the collector electrode; and an electric circuit provided on the support substrate, in which the multilayer wiring layer includes a wire electrically connecting the collector wire and the electric circuit.

<12> A method for manufacturing a semiconductor device. The method includes forming a release layer on a surface of a temporary substrate facing in a first direction; forming a collector layer including a compound semiconductor of a first conductor type on a surface of the release layer facing in the first direction; forming a base layer including a compound semiconductor of a second conductor type opposite from the first conductor type, on a surface of the collector layer facing in the first direction; forming at least one emitter mesa including a compound semiconductor of the first conductor type on a surface of the base layer facing in the first direction; forming a base electrode continuously surrounding the emitter mesa in plan view, on the surface of the base layer facing in the first direction; forming an emitter electrode on a surface of the emitter mesa facing in the first direction; separating the collector layer from the temporary substrate by etching and removing the release layer; forming a collector electrode on a surface of the collector layer facing in a second direction opposite to the first direction; and joining the collector electrode to a support substrate.

<13> The method for manufacturing a semiconductor device according to the item <12>, in which the base electrode includes two layers including a first layer and a second layer, each of the first layer and the second layer includes no closed pattern, the first layer and the second layer as a whole continuously surround the emitter mesa, and, in the forming the base electrode, the first layer is formed by a lift-off process, and the second layer is then formed by another lift-off process.

What is claimed is:

1. A semiconductor device comprising:
a collector layer including a compound semiconductor of a first conductor type;
a base layer on a surface of the collector layer facing in a first direction and including a compound semiconductor of a second conductor type opposite from the first conductor type;
at least one emitter mesa on a partial region of a surface of the base layer facing in the first direction and including a compound semiconductor of the first conductor type, the at least one emitter mesa forming a heterojunction with the base layer;
a collector electrode on a surface of the collector layer facing in a second direction opposite to the first direction;
an emitter electrode on a surface of the emitter mesa facing in the first direction;
a base electrode on a region, in the surface of the base layer facing in the first direction, on which the emitter mesa is not present, wherein
the base electrode includes a first layer and a second layer, a portion of the first layer overlaps a portion of the second layer, each of the first layer and the second layer includes no closed pattern in plan view, and the first layer and the second layer as a whole continuously surround the emitter mesa in plan view.

2. The semiconductor device according to claim 1, wherein
the emitter mesa has a circular shape, a square shape, a rectangular shape, or a regular hexagonal shape in plan view.

3. The semiconductor device according to claim 1, wherein
the at least one emitter mesa comprises multiple emitter mesas, the multiple emitter mesas are disposed discretely,
the base electrode continuously surrounds each of the emitter mesas, and a portion of the base electrode between two adjacent emitter mesas of the multiple emitter mesas is shared as a portion surrounding the emitter mesas on both sides.

4. The semiconductor device according to claim 3, wherein
at least a portion of the base electrode has, in plan view, a lattice shape in which vertical and horizontal lines are orthogonal to each other, and
the multiple emitter mesas are in respective multiple divisions surrounded by the vertical and horizontal lines of the lattice shape.

5. The semiconductor device according to claim 3, wherein
at least a portion of the base electrode has a honeycomb shape in plan view, and
the multiple emitter mesas are in respective multiple divisions of the honeycomb shape.

6. The semiconductor device according to claim 4, wherein,
in plan view, an outer peripheral line of each of the multiple emitter mesas faces an edge of the base electrode with a gap therebetween and has a shape along the edge of the base electrode.

7. The semiconductor device according to claim 3, wherein
the emitter mesa includes a ballast resistor layer.

8. The semiconductor device according to claim 1, further comprising:
an emitter bump for external circuit connection, wherein
the emitter bump is on a side ahead in the first direction when viewed from the emitter electrode and at a position where the emitter bump partially overlaps the emitter electrode in plan view.

9. The semiconductor device according to claim 1, further comprising:
a support substrate on a surface of the collector electrode facing in the second direction, wherein
a thermal conductivity of the support substrate is higher than a thermal conductivity of the collector layer.

10. The semiconductor device according to claim 9, further comprising:
a collector wire on a surface of the support substrate facing in the first direction, the collector wire being electrically connected to the collector electrode and extending outside the collector electrode in plan view; and
a collector bump, for external circuit connection, on a side ahead in the first direction when viewed from the collector wire, the collector bump being at a position, in the collector wire, at which the collector bump does not overlap the collector electrode in plan view, the collector bump being electrically connected to the collector wire.

11. The semiconductor device according to claim 9, further comprising:
a multilayer wiring layer on a surface of the support substrate facing in the first direction;
a collector wire on a surface of the multilayer wiring layer facing in the first direction and electrically connected to the collector electrode; and
an electric circuit on the support substrate, wherein
the multilayer wiring layer includes a wire electrically connecting the collector wire and the electric circuit.

12. The semiconductor device according to claim 5, wherein,
in plan view, an outer peripheral line of each of the multiple emitter mesas faces an edge of the base electrode with a gap therebetween and has a shape along the edge of the base electrode.

13. The semiconductor device according to claim 4, wherein
the emitter mesa includes a ballast resistor layer.

14. The semiconductor device according to claim 5, wherein
the emitter mesa includes a ballast resistor layer.

15. The semiconductor device according to claim 2, further comprising:
an emitter bump for external circuit connection, wherein
the emitter bump is on a side ahead in the first direction when viewed from the emitter electrode and at a position where the emitter bump partially overlaps the emitter electrode in plan view.

16. The semiconductor device according to claim 3, further comprising:
an emitter bump for external circuit connection, wherein
the emitter bump is on a side ahead in the first direction when viewed from the emitter electrode and at a position where the emitter bump partially overlaps the emitter electrode in plan view.

17. The semiconductor device according to claim 2, further comprising:
a support substrate on a surface of the collector electrode facing in the second direction, wherein
a thermal conductivity of the support substrate is higher than a thermal conductivity of the collector layer.

18. The semiconductor device according to claim 3, further comprising:
a support substrate on a surface of the collector electrode facing in the second direction, wherein
a thermal conductivity of the support substrate is higher than a thermal conductivity of the collector layer.

19. A method for manufacturing a semiconductor device, the method comprising:
forming a release layer on a surface of a temporary substrate facing in a first direction;
forming a collector layer including a compound semiconductor of a first conductor type on a surface of the release layer facing in the first direction;
forming a base layer including a compound semiconductor of a second conductor type opposite from the first conductor type, on a surface of the collector layer facing in the first direction;
forming at least one emitter mesa including a compound semiconductor of the first conductor type on a surface of the base layer facing in the first direction;
forming a base electrode continuously surrounding the emitter mesa in plan view, on the surface of the base layer facing in the first direction;
forming an emitter electrode on a surface of the emitter mesa facing in the first direction;
separating the collector layer from the temporary substrate by etching and removing the release layer;
forming a collector electrode on a surface of the collector layer facing in a second direction opposite to the first direction; and
joining the collector electrode to a support substrate.

20. The method for manufacturing a semiconductor device according to claim 19, wherein
the base electrode includes two layers including a first layer and a second layer, each of the first layer and the second layer includes no closed pattern, the first layer and the second layer as a whole continuously surround the emitter mesa, and,
in the forming the base electrode, the first layer is formed by a lift-off process, and the second layer is then formed by another lift-off process.
